(19) United States
(12) Patent Application Publication
(10) Pub. No.: US 2026/0047395 A1
(43) Pub. Date: Feb. 12, 2026

(54) Inline Detection and Repair System

(71) Applicant: Applied Materials, Inc., Santa Clara, CA (US)

(72) Inventors: Sarah WOZNY, Austin, TX (US); Bernhard Gunter MUELLER, Finsing (DE); Nikolai KNAUB, Munich (DE)

(21) Appl. No.: 18/796,803

(22) Filed: Aug. 7, 2024

(51) Int. Cl. H01L 21/66; H01L 21/768

(52) U.S. Cl. CPC H01L 22/12; H01L 21/76892

(57) ABSTRACT

A method for performing an inline detection and repair of a defect on a substrate or interposer that does not destroy the substrate or interposer. The method is performed in the manufacturing area in separate platforms or a single platform. In some embodiments, the method may include detecting a defect on a panel in line to a panel level packaging process using an electron beam to image at least a portion of a surface of the panel, identifying a type of the defect, and repairing the defect on the panel based on the type of the defect in line with the panel level packaging process using a material removal process to remove material to fix a defect or using the electron beam in conjunction with a precursor gas to deposit material to fix a defect. The material removal process may include a plasma beam or an ion beam.

### FIELD

Embodiments of the present principles generally relate to semiconductor processing of semiconductor substrates.

### BACKGROUND

Packaging processes connect devices on a substrate to each other. As technology progresses, the density of the packaging increases and the line/space of the interconnects decreases. Detection of defects on sub-micron and smaller line/space is difficult. Typically, the packaging process is completed and then tested. If faults are detected through voltage contrast testing and the like, the substrate is cut apart and sent out to be inspected using high-definition imaging devices. Regardless of whether or not a defect is found, the substrate is scrapped as the substrate has been cut apart. The inventors have also observed that a substantial amount of time is lost to sending out and waiting for the test results to return. In addition, if defects are found, many packages may have already been produced by the time the results have arrived.

Accordingly, the inventors have provided methods and apparatus for providing inline detection and repair of substrates including large format panel substrates for panel level packaging and other applications.

### SUMMARY

Methods and apparatus for inline detection and repair of substrate or interposer defects are provided herein.

In some embodiments, a method for inline detection and repair of a defect on a substrate or interposer may comprise detecting the defect on the substrate or interposer in line with a packaging process, identifying a type of the defect, and repairing the defect on the substrate or interposer based on the type of the defect and in line with the packaging process.

In some embodiments, the method may further include repairing the defect to prevent loss of the substrate or interposer in a semiconductor packaging process, detection of the defect and repair of the defect are performed on a single platform that includes a defect detection process, a material removal process, and a material deposition process, a type of a defect that is an electrical short circuit or an electrical open circuit of an interconnect of a redistribution layer (RDL), an electrical short circuit that is repaired using an ion beam or a plasma beam to remove metal material to open the electrical short circuit of the interconnect, an electrical open circuit that is repaired using an electron beam and a precursor gas to deposit metal material to close the electrical open circuit of the interconnect, repairing the defect includes using an electron beam and a precursor gas to deposit dielectric material on the substrate or interposer, a substrate or interposer that is a rectangular panel and the packaging process is a panel level packaging process, a rectangular panel that is approximately 515 mm by 510 mm in length and width, detecting defects, identifying defects, or repairing defects that is assisted by an artificial intelligence process, an artificial intelligence process that uses a design file and prior defect data to infer possible defect locations to scan on the substrate or interposer to reduce defect scanning durations, an artificial intelligence process that uses a design file to infer repairs to defects on the substrate or interposer to maintain performance of structures on the substrate or interposer within a predetermined boundary limit of performance criterion of the design file, and/or a defect that has a size that is in a sub-micron range.

In some embodiments, a method for inline detection and repair of a defect on a panel may comprise detecting the defect on the panel in line with a panel level packaging process using an electron beam to image at least a portion of a surface of the panel, identifying a type of the defect, and repairing the defect in-situ on the panel based on the type of the defect and in line with the panel level packaging process using a material removal process or using a material deposition process that includes the electron beam in conjunction with a precursor gas to deposit material.

In some embodiments, the method may further include a defect that has a size that is in a sub-micron range, detection of the defect and repair of the defect that are performed on a single platform that includes the material removal process and the material deposition process, a type of a defect is an electrical short circuit of an interconnect of a redistribution layer (RDL) which is repaired by removal of a material by the material removal process or an electrical open circuit of the interconnect of the redistribution layer (RDL) which is repaired by deposition of a material by the material deposition process using the electron beam and the precursor gas, a material removal process that includes an ion beam or a plasma beam, and/or detecting defects, identifying defects, or repairing defects that is assisted by an artificial intelligence process and where the artificial intelligence process uses a design file and prior defect data to infer possible defect locations to scan on the panel to reduce defect scanning durations or where the artificial intelligence process uses a design file to infer repairs to defects on the panel to maintain performance of structures on the panel within a predetermined boundary limit of performance criterion of the design file.

In some embodiments, a non-transitory, computer readable medium having instructions stored thereon that, when executed, cause a method for inline detection and repair of a defect on a substrate or interposer to be performed, the method may comprise detecting the defect on the substrate or interposer in line with a packaging process, identifying a type of the defect, and repairing the defect on the substrate or interposer based on the type of the defect and in line with the packaging process.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for inline detection and repair of a defect on a substrate in accordance with some embodiments of the present principles.

FIG. 2 depicts an isometric view of a panel substrate in accordance with some embodiments of the present principles.

FIG. 3 depicts a cross-sectional view of a warped panel in accordance with some embodiments of the present principles.

FIG. 4 depicts an isometric view of a twisted panel in accordance with some embodiments of the present principles.

FIG. 5 depicts isometric views and a cross-sectional view of a short circuit defect in a panel in accordance with some embodiments of the present principles.

FIG. 6 depicts isometric views and a cross-sectional view of an open circuit defect in a panel in accordance with some embodiments of the present principles.

FIG. 7 depicts a top-down view and a cross-sectional view of a panel with a dielectric defect in accordance with some embodiments of the present principles.

FIG. 8 depicts a cross-sectional view of an apparatus for inline detection and repair of defects on a substrate in accordance with some embodiments of the present principles.

FIG. 9 depicts a cross-section view of a system for inline detection and repair of defects in a panel level packaging process in accordance with some embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide inline detection and repair of substrate and interposer defects for packaging processes. Defects, such as electrical shorts and open circuits can be detected and repaired without the loss of the substrate and in line with the packaging process, substantially increasing yields. The present techniques leverage ion beam and electron beam technologies to advantageously allow for detection and repair of defects in the nanometer range, detecting and repairing high-density packaging substrates with fine line/spacing (L/S) of two microns and below.

Artificial intelligence processing demands increased calculation power and speed. To meet the demands, panel-based semiconductor architectures are used to alter the way the structures are packaged to reduce interconnect lengths, increasing the speed of chiplet communications. Currently, with chip level packaging, further increases in speed and calculation power is difficult because the chips are already at the atomic level with no known means to get smaller than atomic sizes. One way to overcome the limitations of wafer level packaging is to use panels to decrease the interconnect lengths through changes in architecture, allowing the chiplets to have much faster communication speeds, and thus, more calculation power. The new panel architectures have very fine line/space interconnects (i.e., fine conductive line widths with close spacing between the lines). With current processes, such as laser-based technologies, the line/space criteria become a limiting factor because laser-technologies cannot be used in a nanometer range.

The laser tools have a resolution up to a few micrometers and are standalone tools that need input data from an upstream standalone metrology tool to locate the defect coordinates. The present technologies provide greatly improved resolutions ranging from sub-micron down to nanometer scale features while being directly integrated on an inline metrology tool, allowing for a fully integrated process with semiconductor packaging processes. In some embodiments, panel level electron and ion-beam technology are used to identify and subsequently repair sub-micrometer defects (e.g., but not limited to, electrical open and short circuits, etc.) for large form factor technologies such as panels used for substrates, fan out, and interposer applications with fine line/space (two micrometer and below). The techniques provide, for example, inline repair capabilities for electrical circuits with fine line/space that is currently not available by supplying higher resolution repair capabilities compared to laser-based systems, reducing yield loss, especially for high circuit density applications. Cycle time is also dramatically improved with the ability of inline metrology and repair capabilities to find and repair defects in one inline process. The techniques can provide inline repair for open circuits by enabling conductive material deposition in advanced substrate build-up and interconnect layers and interposer and/or fan out applications. The techniques also provide inline repair of short circuits by ablating conductive materials at the short location.

In some embodiments using panel level electron and ion-beam technology system inline images can be matched to a design file through pattern recognition and the defect location and a defect type can then be identified. Once the defect (e.g., an open or short) is identified, the beams (either ion, plasma, or electrons) can be used to either deposit or remove a thin layer of materials where needed to repair the defect. For example, for electrical shorts, the ion (high precision, lower speed) or plasma beam (lower precision, higher speed) is used for material ablation on the substrate at the defect location under high vacuum. The accelerating voltage, used in conjunction with the ultra-high vacuum, is critically controlled to avoid redeposition/recast from volatile species in the system chamber. For electrical opens, the system may include a metal deposition cartridge capability that is compatible with the metallization used in the electrical circuit. A small amount of metal is then subsequently, precisely, and locally deposited where lacking, in order to establish an electrical connection and repair the feature, saving the substrate. The substrate can then continue to downstream packaging processes without incurring yield loss due to, for example, electrical shorts or opens.

As used herein, ‘inline’ refers to a process or apparatus that is compatible with a packaging process routine or line. If a process is ‘in line’ or an ‘inline process,’ the process can be completed without the removal and destruction of a substrate from the packaging process routine. For example, an inline process has the capability to detect and perform a repair and then return the substrate or interposer to the packaging process routine, without the loss of the substrate or interposer. Traditional metrology and testing processes are typically destructive in nature (substrate or interposer is cut apart for testing, etc.) and require removal and destruction of the substrate or interposer after the packaging process is complete, causing loss of the substrate or interposer and all associated packages and/or interconnections.

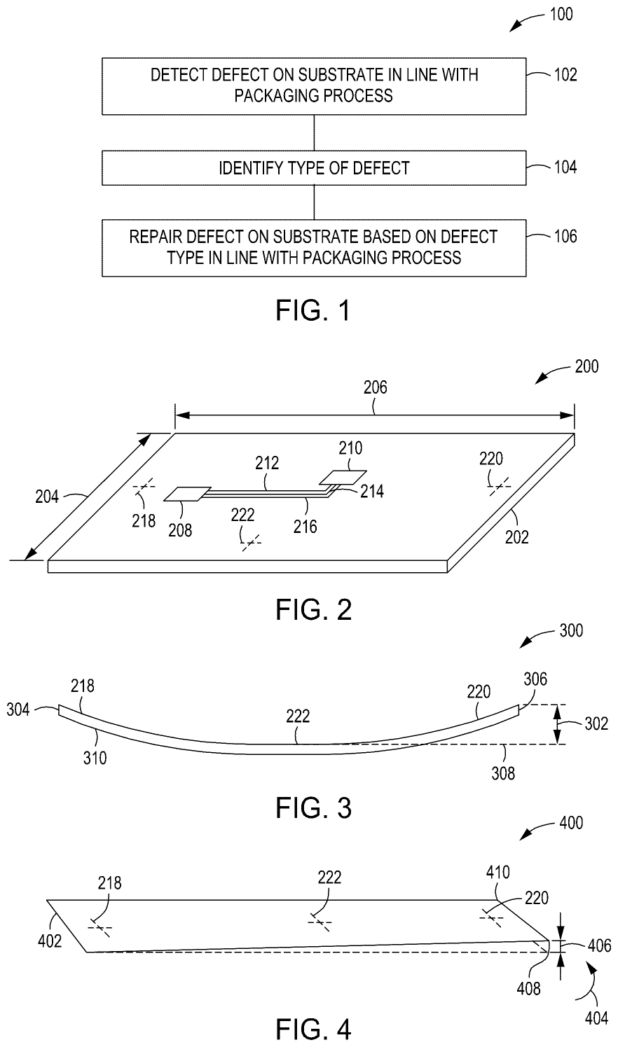

FIG. 1 is a method 100 for inline detection and repair of a defect on a substrate. The method 100 is applicable to the repair of substrates or interposers, but, for the sake of brevity, the method 100 is discussed with regard to substrates. References are made to FIGS. 2-7 in the discussion of the method 100. FIG. 2 depicts an example of a panel 202 or advanced substrate in a view 200. The example substrates used herein are panel substrates, but the present techniques are not limited only to panel substrates or only to packaging processes. The present techniques can also be applied to traditional wafer repair and to front-end-of-line (FEOL) structure formation as well as back-end-of-line (BEOL) packaging processes. For the sake of brevity, the examples use a panel 202 involved in a panel level packaging process. The panel 202 presents many additional challenges during processing compared to traditional round wafer substrates due to the size and also the materials used in the panel 202. While a wafer may be 200 mm or 300 mm in size, the panel 202 may have a width 204 of approximately 510 mm and a length 206 of approximately 515 mm or larger (can be quadruple or more the size of a traditional wafer). The panel 202 may also be composed of a glass or organic-based material as opposed to silicon used in wafers. The organic-based materials can cause outgassing during processing which must be addressed for successful processing.

In the example of the panel 202, a first chiplet 208 is connected to a second chiplet 210 via a first interconnect 212, a second interconnect 214, and a third interconnect 216. The interconnects are generally formed during packaging processes that form redistribution layers (RDLs) on the panel 202. Due to the size of the panel 202, more than one reference point may be used to navigate over the panel 202 as opposed to traditional wafers that may use a single global navigation reference. In the example, a first reference point 218, a second reference point 220, and a third reference point 222 is used as example intermediate navigational reference points. The large size of the panel 202 also tends to emphasize issues that may be minor in wafer substrates. For example, as depicted in a view 300 of FIG. 3, warpage or bow of the panel 202 is much greater for the panel 202 than for a smaller round wafer. In the example of view 300, a first end 304 of the panel 202 and a second end 306 of the panel 310 are warped upwards (in some examples, the panel 310 can be warped downward as well). The amount 302 of warpage can be, for example, up to approximately 4 mm or more. The warpage is exaggerated in the view 300 to show more detail.

The warpage presents difficulties during navigation of the panel 310, especially when attempting to repair a defect with precision. Apparatus that needs to be precisely positioned and focused above a defect must also take into account the warpage, as the defect surface height (distance above the normal surface plane 308) may be changed due to the warpage. For example, the third reference point 222 is at the normal surface plane 308 while the first reference point 218 and the second reference point 220 are substantially higher than the normal surface plane 308. Due to the height variation caused by the warpage, the reference points may include not only an X and Y location information but Z height data as well. In a view 400 of FIG. 4, the panel 402 has a twist 404 that may be considered during the detect and repair processes. The amount 406 of twist 404 at the corner 408 (relative to the corner 410) affects the Z height data of the second reference point 220 and the third reference point 222 while minimally affecting the first reference point 218. Z height data allows for enhanced focusing of the apparatus for detection and repair. The above examples are not meant to be limiting as to the types of warpage that can be overcome with the present principles. Other types of warpage may be encountered as well and successfully repaired using the present techniques. As the examples illustrate, navigation over the surface of the panels presents difficulties not only due to the large area of the surface but also due to large amounts and different types of warpage and height variations. In addition, outgassing of the organic materials of the panels also presents unique challenges not found with traditional wafers.

In block 102 of the method of FIG. 1, a defect is detected on a substrate in line with a packaging process. The defect may be detected using an image from an electron beam that is directed at a surface location on a substrate. The position on the surface of the substrate to look for a defect may be determined based on a design file and/or prior data collected during previous detection and repair operations. In some embodiments, the position may be determined using artificial intelligence processes based on the design file information and/or the prior data collected during previous detection and repair operations to infer likely locations for defects to occur. In general, scanning the entire surface of the substrate is too time consuming. A trade-off may occur between the amount of time spent on scanning high probability locations of defects versus the increase in yield achieved by scanning for and repairing all defects. For example, if 20 locations out of 1000 produce 90% of all defects, detection of defects at the 20 locations may possibly increase the yield by 20% (assuming a defect rate of 22%). Scanning of, for example, the additional 980 locations for locating the remaining 10% of possible defects would achieve only a 2% increase in yield, but a substantial decrease in throughput.

In block 104, the type of defect is identified based on the image from the electron beam. In some embodiments, the image from the electron beam can be compared to previously acquired images from other substrates and/or compared to the design file to determine the type of defect such as, but not limited to, an open circuit or a short circuit and the like. In some embodiments, the defect type may also be distinguished by the material type of defect such as a metal material defect and/or a dielectric material defect. For example, a metal surface that is supposed to be covered with an insulating material is typed as a dielectric material defect as opposed to a metal material defect (short or open, etc.). The type of defect information is used to determine what type of repair is needed. In block 106, the defect on the substrate is repaired in line with the packaging process based on the defect type. The actual repair may be accomplished using a plasma beam, an ion beam, or an electron beam with or without gas depending on the defect type. The plasma beam and the ion beam can be used to ablate metal material to repair shorts while the electron beam can be used with gases to deposit metal material to repair shorts and/or to repair dielectric material. The plasma beam is faster (three to four times as fast compared to ion) at removing material but less precise than the ion beam. For L/S of approximately 1/1 microns (line widths of 1 micron spaced 1 micron apart) and above, the plasma beam may be sufficient.

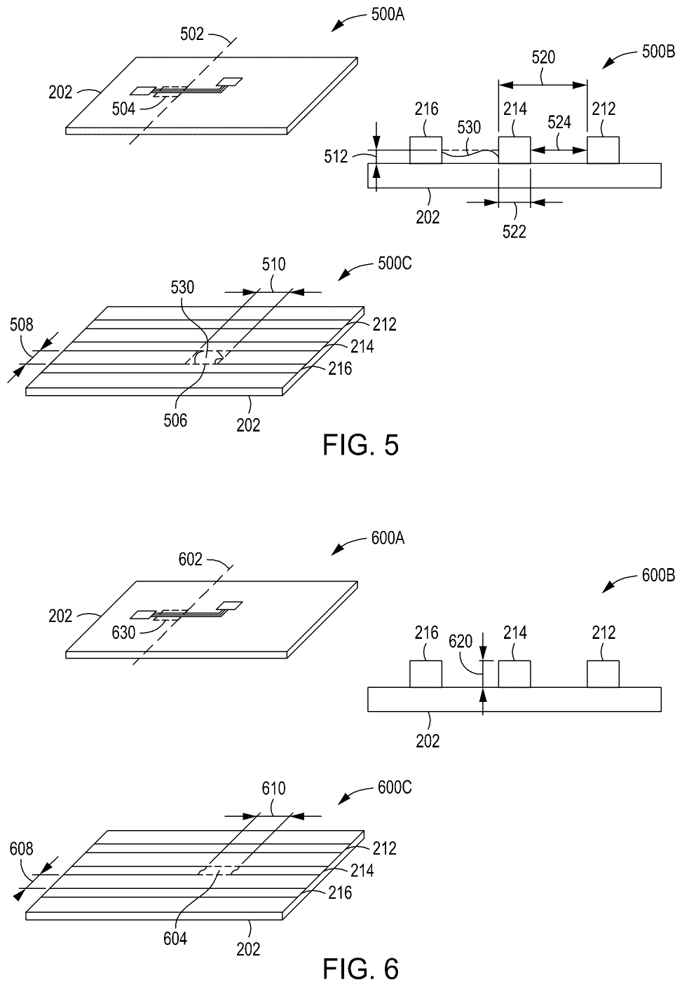

FIG. 5 is an example of a detection and repair of a short circuit 530 on the panel 202. In an isometric view 500A, a cross-sectional cutline 502 across the interconnects between the chiplets is depicted in a cross-sectional view 500B. The short circuit 530 is a conductive material that has electrically shorted the second interconnect 214 and the third interconnect 216. The pitch 520 of the interconnects has a width 522 (line) and a space 524 which can be in the sub-micron or nanometer range, requiring very precise control to remove the short circuit 530. During detection, information relating to the height 512 of the material (e.g., average height, peak height, valley height, etc.) may be established from image contrast data and the like. In an isometric view 500C of the portion 504 of the panel 202 of the isometric view 500A, detection data may include the area (e.g., average or actual length 510 by the average or actual width 508, etc.) of the short circuit 530. With the height, length, and width data, the volume of the short circuit 530 can be obtained. The data may also be used to determine a repair area 506 that is calculated to ensure a complete and successful repair. The repair area 506 can be an estimated area with a margin (e.g., 1% or 2%, etc.) to account for averaging errors and/or based on prior repair successes. In some embodiments, the electron beam and the plasma beam or ion beam may all be focused at the detection location and no further navigation is required to both detect and repair the short circuit 530. If the detection apparatus and the repair apparatus use different chambers, the detection data (location, type, material, size, etc.) can be passed to the repair apparatus so that the repair apparatus can be positioned at that location on the panel to complete repairs. The removal of the material is accomplished by directing ions or plasma at the substrate. Having the size and volumetric data allows for the repair apparatus to accurately ablate (i.e., gradually remove material by melting, evaporation, frictional action, and/or erosion of the material) or remove the short circuit 530 and allow the panel to continue on in the packaging process line.

FIG. 6 is an example of a detection and a repair of an open circuit 604 on the panel 202. In an isometric view 600A, a cross-sectional cutline 602 across the interconnects between the chiplets is depicted in a cross-sectional view 600B. The open circuit 604 is a loss of conductive material that creates an electrical open circuit of the second interconnect 214 between the chiplets. During detection, information relating to the height 620 of the second interconnect 214 may be established from image contrast data and/or from the design file and the like. In an isometric view 600C of the portion 630 of the panel 202 of the isometric view 600A, detection data may include the area (e.g., average or actual length 610 by the average or actual width 608, etc.) of the open circuit 604. Width data may also be sourced from the design file. With the height, length, and width data, the volume of the open circuit 604 can be obtained. In some embodiments, the electron beam is used to immediately repair the open circuit 604 and no further navigation is required to both detect and repair the open circuit 604. If the detection and repair are performed at different times, the detection data (location, type, material, size, etc.) can be stored so that the repair apparatus can be positioned at that location on the panel at another point in time. The adding of the material is accomplished by directing the electron beam at the defect location in conjunction with a precursor gas selected to deposit the appropriate material per the design file and the like. Having the size and volumetric data allows for the repair apparatus to accurately deposit metal material on the open circuit 604 and allow the panel to continue on in the packaging process line.

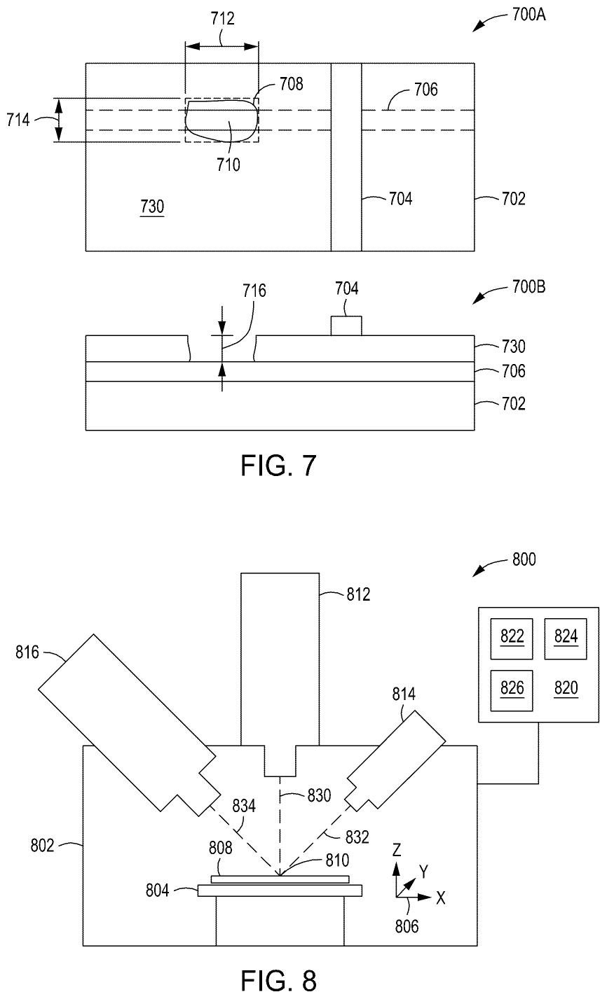

FIG. 7 is an example of a detection and a repair of a dielectric defect on the panel 202. In the top-down view 700A of FIG. 7, a portion 702 of a substrate includes an embedded interconnect 706 that was not fully covered by the conformal dielectric layer 730, leaving the dielectric defect 708 in the conformal dielectric layer 730 with an exposed portion 710 of the embedded interconnect 706. A second interconnect 704 is formed on top of the conformal dielectric layer (RDL). If a third interconnect were to be formed on the exposed portion 710 of the embedded interconnect 706, a short would occur. In the example, repair of the exposed portion 710 is necessary before the packaging process can proceed. During detection, information relating to the depth 716 of the embedded interconnect 706 as depicted in the cross-sectional view 700B may be established from image contrast data and/or from the design file and the like. The detection data may include the area (e.g., average or actual length 712 by the average or actual width 714, etc.) of the dielectric defect 708. With the height, length, and width data, the volume of the dielectric defect 708 can be obtained. In some embodiments, the electron beam is used to immediately repair the dielectric defect 708 and no further navigation is required to both detect and repair the dielectric defect 708. If the detection and repair are completed at different times, the detection data (location, type, material, size, etc.) can be stored so that the repair apparatus can be positioned at that location on the panel at another point in time. The adding of the dielectric material is accomplished by directing the electron beam at the defect location in conjunction with a precursor gas selected to deposit the appropriate dielectric material per the design file and the like. Having the size and volumetric data allows for the repair apparatus to accurately deposit dielectric material on the dielectric defect 708 and allow the panel to continue on in the packaging process line.

FIG. 8 depicts an inline defect and repair apparatus 800 that includes defect detection apparatus, a material removal apparatus, and a material deposition apparatus. The defect detection apparatus may include an electron beam source 812 with imaging capabilities. The material deposition apparatus may include the electron beam source 812 and a gas source 814. The material removal apparatus may include a plasma beam or an ion beam source 816. The ion beam, for example, but not limited to, can be a gallium or helium-based ion beam depending on the application. The sources may also incorporate autofocus features that can be leveraged to determine volumetric information about the defects. In some embodiments, the material removal apparatus may be a separate chamber and not a single chamber as depicted in FIG. 8. The inline defect and repair apparatus 800 also include a chamber 802 that allows for a vacuum environment to be established during processing of the panel 808 supported by a movable pedestal 804. In some embodiments, the movable pedestal 804 may move in the X and Y directions. In some embodiments, the movable pedestal 804 may move in the X, Y, and Z directions 806 to help compensate for height variations of the panel. The focal points of the electron beam 830 from the electron beam source 812, the gas 832 from the gas source 814, and the ion or plasma beam 834 from the plasma beam or ion beam source 816 converge onto a single location 810 on the panel 808. The converged focal points allow for detection and repair without moving the panel, saving time and reducing navigational errors. In some embodiments, all detection of defects on the panel may occur first followed by all repair of the defects which will require reacquisition of the defect location from the defect detection process in order to subsequently perform the repairs.

The inline defect and repair apparatus 800 also includes a controller 820. The controller 820 controls the operation of any of the inline detection and repair apparatus and processes described herein, including the inline detect and repair apparatus 800. The controller 820 may use a direct control of the inline detect and repair apparatus 800, or alternatively, by controlling the computers (or controllers) associated with the individual apparatus of the inline detect and repair apparatus 800. In operation, the controller 820 enables data collection and feedback from the inline detect and repair apparatus 800 to optimize performance of the inline detect and repair apparatus 800 and to control the processing flow according to methods described herein such as detecting defects, identifying the types of defects, and repairing the defects. The controller 820 generally includes a central processing unit (CPU) 822, a memory 824, and a support circuit 826. The CPU 822 may be any form of a general-purpose computer processor that can be used in an industrial setting. The support circuit 826 is conventionally coupled to the CPU 822 and may comprise a cache, clock circuits, input/output subsystems, power supplies, and the like. Software routines, such as methods as described herein may be stored in the memory 824 and, when executed by the CPU 822, transform the CPU 822 into a specific purpose computer (controller 820). The software routines may also be stored and/or executed by a second controller (not shown) that is located remotely from the inline detect and repair apparatus 800.

The memory 824 is in the form of computer-readable storage media that contains instructions, when executed by the CPU 822, to facilitate the operation of the semiconductor processes and equipment. The instructions in the memory 824 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

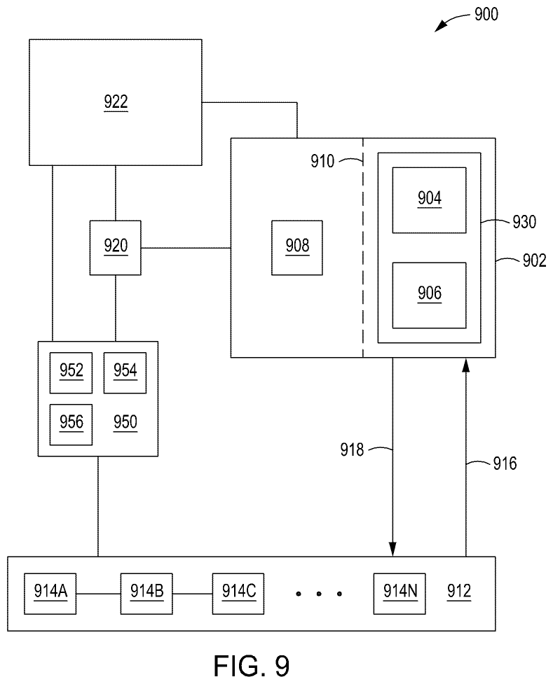

FIG. 9 is an inline defect and repair system 900 that includes an inline defect and repair apparatus 902, a controller 950, a design file 920, and a detection and repair analysis apparatus 922. The inline defect and repair system 900 interfaces with a packaging process line 912. The packaging process line may include one or more processes such as a first process 914A, a second process 914B, a third process 914C, and so on to an Nth process 914N. The inline defect and repair apparatus 902 may be a single platform (as depicted) or on two or more platforms as indicated by dashed line 910. A substrate may be sent to 916 the inline defect and repair apparatus 902 before or after any of the N-processes of the packaging process line 912. Once successfully repaired, the substrate may be returned 918 to the packaging process line 912 at the appropriate point in one of the N-processes. In some instances, the substrate may be transferred to the inline defect and repair apparatus 902 if a voltage contrast check on a layer of an RDL indicates a problem. Layer-by-layer checks help ensure that a completed RDL process will meet the package performance specifications as the packaging process is performed, prior to defects that would cause the substrate to be discarded. Having an inline defect and repair apparatus eliminates the need to cut apart the substrate and send the substrate to an outside laboratory for testing, possibly incurring downtime while results are pending. Another benefit of the inline defect and repair apparatus 902 is the feedback obtained during the packaging process that can then be used to further optimize the process or, if the defect is a killer defect, stop processing substrates that will need to be scrapped, preventing the wasting of materials and time. In some embodiments, the inline defect and repair apparatus 902 may be integrated into a cluster tool and the like to reduce transport time between any package processing chambers.

The inline defect and repair apparatus 902 includes a defect detection apparatus 904, a material removal apparatus 908, and a material deposition apparatus 930 which includes the defect detection apparatus 904 and the gas apparatus 906. The defect detection apparatus 904 includes an electron beam source and detector and the like capable of obtaining images of the surface of the substrate to aid in detection of defects on the substrate. The material removal apparatus 908 may include, in some embodiments, a plasma beam source or an ion beam source and the like that is capable of ablating material from the surface of the substrate. The material deposition apparatus 930 may include an electron beam source and a gas source and the like that is capable of depositing metal and/or dielectric materials on the surface of the substrate.

The inline defect and repair system 900 also includes a controller 950. The controller 950 controls the operation of any of the inline detection and repair apparatus/systems and processes described herein, including the inline detect and repair system 900. The controller 950 may use a direct control of the inline detect and repair system 900, or alternatively, by controlling the computers (or controllers) associated with the individual apparatus/systems of the inline detect and repair system 900. In operation, the controller 950 enables data collection and feedback from the inline detect and repair system 900 to optimize performance of the inline detect and repair system 900 and to control the processing flow according to methods described herein such as detecting defects, analyzing and identifying the types of defects, and repairing the defects. The controller 950 generally includes a central processing unit (CPU) 952, a memory 954, and a support circuit 956. The CPU 952 may be any form of a general-purpose computer processor that can be used in an industrial setting. The support circuit 956 is conventionally coupled to the CPU 952 and may comprise a cache, clock circuits, input/output subsystems, power supplies, and the like. Software routines, such as methods as described herein may be stored in the memory 954 and, when executed by the CPU 952, transform the CPU 952 into a specific purpose computer (controller 950). The software routines may also be stored and/or executed by a second controller (not shown) that is located remotely from the inline detect and repair system 900.

The memory 954 is in the form of computer-readable storage media that contains instructions, when executed by the CPU 952, to facilitate the operation of the semiconductor processes and equipment. The instructions in the memory 954 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The detection and repair analysis apparatus 922 is an artificial intelligence (AI)-based apparatus with computing and storage capabilities. The detection and repair analysis apparatus 922 analyzes data and/or images obtained from the inline detection and repair apparatus 902, from the design file 920, and/or from the controller 950. Data may also be manually input into the detection and repair analysis apparatus 922 by an operator. For example, data files from prior packaging processes and/or prior packaging defects and the like may be manually entered if not stored from previous packaging runs by the inline detection and repair apparatus 902 and like. In some embodiments, data may be obtained directly from the packaging process line 912. Inferences can be drawn from the data by the detection and repair analysis apparatus 922 to determine locations for the inline detection and repair apparatus 902 to aid in quickly locating and repairing defects in high probability locations on the substrate. Inferences can also be made as to the type of defect, the optimal form of repair, the optimal materials for repair, and/or the optimal process for removing a particular type of material and the like. In some embodiments, the detection and repair analysis apparatus 922 may receive image data from the inline detection and repair apparatus 902, analyze the image and create repair boundaries to facilitate in focusing the inline detection and repair apparatus 902 on specific portions of the defect for the actual repair. The boundaries help to minimize the repaired area and/or volume to allow for quick repairs while ensuring that the repair is sufficient to not adversely affect performance of the final package. The detection and repair analysis apparatus 922 knows from the design file 920, for example, that an interconnect width is 12 nm and using the focus capabilities of the inline detection and repair apparatus 902, the detection and repair analysis apparatus 922 can determine the volume of metal to deposit.

In some embodiments, the detection and repair analysis apparatus 922 may automatically create a process recipe for defect detection and repair as a function of the design file 920 and/or make recommendations in terms of changes to the design file 920. In some embodiments, boundaries may be predetermined to limit the changes that may automatically occur to the design file 920, such as limiting changes that would affect less than 1% or 2% of the desired performance and the like. In some embodiments, suggested changes may be presented to an operator for approval before the changes are incorporated. In some embodiments, the detection and repair analysis apparatus 922 may infer high probability defect locations to reduce the number of scanned locations of a substrate by the inline defect and repair apparatus 902 to reduce scanning time in order to increase throughput. The detection and repair analysis apparatus 922 may also use defect type information and location data to determine a performance impact to the packaging and/or determine which locations have the highest level of priority to be repaired.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for inline detection and repair of a defect on a substrate or interposer, comprising:
detecting the defect on the substrate or interposer in line with a packaging process;
identifying a type of the defect; and
repairing the defect on the substrate or interposer based on the type of the defect and in line with the packaging process.

2. The method of claim 1, wherein repairing the defect prevents loss of the substrate or interposer in a semiconductor packaging process.

3. The method of claim 1, wherein detection of the defect and repair of the defect are performed on a single platform that includes a defect detection process, a material removal process, and a material deposition process.

4. The method of claim 1, wherein the type of the defect is an electrical short circuit or an electrical open circuit of an interconnect of a redistribution layer (RDL).

5. The method of claim 4, wherein the electrical short circuit is repaired using an ion beam or a plasma beam to remove metal material to open the electrical short circuit of the interconnect.

6. The method of claim 4, wherein the electrical open circuit is repaired using an electron beam and a precursor gas to deposit metal material to close the electrical open circuit of the interconnect.

7. The method of claim 1, wherein repairing the defect includes using an electron beam and a precursor gas to deposit dielectric material on the substrate or interposer.

8. The method of claim 1, wherein the substrate or interposer is a rectangular panel and the packaging process is a panel level packaging process.

9. The method of claim 8, wherein the rectangular panel is approximately 515 mm by 510 mm in length and width.

10. The method of claim 1, wherein detecting defects, identifying defects, or repairing defects is assisted by an artificial intelligence process.

11. The method of claim 10, wherein the artificial intelligence process uses a design file and prior defect data to infer possible defect locations to scan on the substrate or interposer to reduce defect scanning durations.

12. The method of claim 10, wherein the artificial intelligence process uses a design file to infer repairs to defects on the substrate or interposer to maintain performance of structures on the substrate or interposer within a predetermined boundary limit of performance criterion of the design file.

13. The method of claim 1, wherein the defect has a size that is in a sub-micron range.

14. A method for inline detection and repair of a defect on a panel, comprising:
detecting the defect on the panel in line with a panel level packaging process using an electron beam to image at least a portion of a surface of the panel;
identifying a type of the defect; and
repairing the defect in-situ on the panel based on the type of the defect and in line with the panel level packaging process using a material removal process or using a material deposition process that includes the electron beam in conjunction with a precursor gas to deposit material.

15. The method of claim 14, wherein the defect has a size that is in a sub-micron range.

16. The method of claim 14, wherein detection of the defect and repair of the defect are performed on a single platform that includes the material removal process and the material deposition process.

17. The method of claim 14, wherein the type of the defect is an electrical short circuit of an interconnect of a redistribution layer (RDL) which is repaired by removal of a material by the material removal process or an electrical open circuit of the interconnect of the redistribution layer (RDL) which is repaired by deposition of a material by the material deposition process using the electron beam and the precursor gas.

18. The method of claim 14, wherein the material removal process includes an ion beam or a plasma beam.

19. The method of claim 14, wherein detecting defects, identifying defects, or repairing defects is assisted by an artificial intelligence process and wherein the artificial intelligence process uses a design file and prior defect data to infer possible defect locations to scan on the panel to reduce defect scanning durations or wherein the artificial intelligence process uses a design file to infer repairs to defects on the panel to maintain performance of structures on the panel within a predetermined boundary limit of performance criterion of the design file.

20. A non-transitory, computer readable medium having instructions stored thereon that, when executed, cause a method for inline detection and repair of a defect on a substrate or interposer to be performed, the method comprising:
detecting the defect on the substrate or interposer in line with a packaging process;
identifying a type of the defect; and
repairing the defect on the substrate or interposer based on the type of the defect and in line with the packaging process.
